(19) United States
(12) Patent Application Publication
(10) Pub. No.: US 2024/0400825 A1
(43) Pub. Date: Dec. 5, 2024

(54) RESIN COMPOSITION, CURED PRODUCT THEREOF, LAMINATE USING SAME, ELECTROSTATIC CHUCK, AND PLASMA PROCESSING EQUIPMENT

(71) Applicant: TORAY INDUSTRIES, INC., Tokyo (JP)

(72) Inventors: Akira Shimada, Otsu-Shi, Shiga (JP); Kazuya Kiguchi, Otsu-shi, Shiga (JP); Yohei Sakabe, Otsu-Shi, Shiga (JP)

(73) Assignee: TORAY INDUSTRIES, INC., Tokyo (JP)

(21) Appl. No.: 18/699,619

(22) PCT Filed: Oct. 5, 2022
(86) PCT No.: PCT/JP2022/037230

§ 371 Date: Apr. 9, 2024

(30) Foreign Application Priority Data
Oct. 19, 2021 (JP) 2021-170659

(51) Int. Cl. C08L 79/08; C08G 77/455; C08K 3/38; C08K 7/18; C09J 7/35; C09J 7/38; C09J 179/08; H01J 37/32

(52) U.S. Cl. CPC C08L 79/08; C08G 77/455; C08K 3/38; C08K 7/18; C09J 7/35; C09J 7/38; C09J 179/08; H01J 37/32715; C08K 2003/385; C08K 2201/005; C08K 2201/006; C08L 2203/162; C09J 2301/302; C09J 2301/304; C09J 2463/00; C09J 2479/08; C09J 2483/00; H01J 2237/3341

(57) ABSTRACT

Disclosed is a thermally conductive sheet that has a high thermal conductivity, a low elastic modulus in a low temperature range of −30° C. or less, and excellent adhesive strength. Also provided is a thermally conductive sheet by using a resin composition containing: (A) a polyimide resin containing a siloxane unit; (B) an epoxy resin; (C) a siloxane diamine; and (D) a thermally conductive filler. Methods of making and using such thermally conductive sheets are also disclosed.

### TECHNICAL FIELD

This disclosure relates to a resin composition that can be suitably used in electronic components and electronic materials. More specifically, this disclosure relates to an adhesive sheet that is used for a thermal interface material or the like and has a high thermal conductivity and a low elastic modulus even at a low temperature.

### BACKGROUND

In plasma processing equipment to perform plasma processing to a semiconductor wafer in a semiconductor manufacturing device, a stage on which the wafer is placed is provided inside a vacuum chamber. The stage mainly includes an electrostatic chuck that attracts and holds the wafer and a cooler that controls the temperature of the electrostatic chuck. In recent years, the density of semiconductor devices such as 3D NAND memories has been increased, and etching processing at a high aspect ratio is required. In the etching processing at a high aspect ratio, since the depth of etching increases, the time required to etch increases, and there is a problem that the cost increases. Therefore, to increase the etching rate, Japanese Patent No. 6621882 discloses a method of etching at a very low temperature of −30° C. or less. For this reason, it is necessary to cool the electrostatic chuck by setting the temperature of the cooler to −30° C. or less. A silicone or acrylic adhesive sheet has been often used heretofore to join the cooler and the electrostatic chuck. However, the adhesive sheet is required to show no peeling or cracking in a low temperature range of −30° C. or less and to have a high thermal conductivity for the purpose of lowering the temperature of the electrostatic chuck.

As a material used for such an adhesive sheet, a composition having improved flexibility and thermal conductivity by adding an inorganic filler having a high heat dissipation property to an acrylic resin or a silicone resin has been proposed (see, for example, Japanese Patent Laid-open Publication No. 2011-151280).

However, when a conventional composition contains a large amount of an inorganic filler, the thermal conductivity of the composition itself is increased, but the elastic modulus is increased in a low temperature range of −30° C. or less so that the thermal stress is increased, and there is a problem that peeling from a base material occurs or a crack is formed in the adhesive sheet.

Therefore, it could be helpful to provide a thermally conductive sheet that has a low elastic modulus in a low temperature range of −30° C. or less and excellent adhesive strength while having a high thermal conductivity because of control of dispersibility of a thermally conductive filler.

### SUMMARY

We provide a resin composition containing (A) a polyimide resin containing a siloxane unit; (B) an epoxy resin; (C) a siloxane diamine; and (D) a thermally conductive filler.

It is possible to obtain an adhesive sheet that has controlled dispersibility of a thermally conductive filler, has a low elastic modulus even in a temperature range of −30° C. or less, has high adhesive strength and elongation at −30° C. or less, and hardly causes peeling or cracking even in a low temperature range of −30° C. or less while having a high thermal conductivity.

### DETAILED DESCRIPTION

A resin composition contains (A) a polyimide resin containing a siloxane unit; (B) an epoxy resin; (C) a siloxane diamine; and (D) a thermally conductive filler.

The polyimide resin (A) containing a siloxane unit used preferably has a weight-average molecular weight of 5,000 or more. By setting the weight-average molecular weight to 5,000 or more, the toughness and flexibility of the thermally conductive sheet can be improved. The weight-average molecular weight is preferably 1,000,000 or less. By setting the weight-average molecular weight to 1,000,000 or less, the dispersibility of the thermally conductive filler (D) can be improved, and the utilization efficiency of the particles can be enhanced from the viewpoint of improving the thermal conductivity.

As a method of measuring the weight-average molecular weight, a solution in which a polyimide containing a siloxane unit is dissolved is used, and the weight-average molecular weight is calculated as a polystyrene conversion weight-average molecular weight using a gel permeation chromatograph (GPC) apparatus.

In addition, the polyimide resin (A) containing a siloxane unit is desirably solvent-soluble. If the polyimide resin is solvent-soluble, the viscosity when the resin composition is adjusted can be lowered, and the dispersibility of the thermally conductive filler can be further improved. The term “solvent-soluble” means that 1 g or more of a substance can be dissolved at 25° C. in 100 g of any organic solvent from among amide solvents such as N-methyl-2-pyrrolidone, N,N-dimethylacetamide, N,N-dimethylformamide, N-vinylpyrrolidone, and N,N-diethylformamide; and ether solvents such as γ-butyrolactone, methyl monoglyme, methyl diglyme, methyl triglyme, ethyl monoglyme, ethyl diglyme, ethylene glycol monomethyl ether, ethylene glycol monoethyl ether, propylene glycol monomethyl ether, propylene glycol monoethyl ether, ethylene glycol dimethyl ether, and ethylene glycol diethyl ether.

The polyimide resin (A) containing a siloxane unit is simply obtained mainly by reacting a tetracarboxylic acid anhydride and a diamine, and has a residue of tetracarboxylic acid anhydride and a residue of the diamine. The polyimide containing a siloxane unit preferably contains a residue corresponding to a tetracarboxylic acid anhydride having a structure represented by following General Formula (1) in an amount of 20 mol % or more when the total amount of residues of tetracarboxylic acid anhydride is 100 mol %. By introducing a siloxane unit into the tetracarboxylic acid anhydride residue, the main chain rigid linearity of the polyimide is lowered, and the glass transition temperature can be lowered, particularly to −30° C. or less. By lowering the glass transition temperature, the elastic modulus at a low temperature can be lowered. From the viewpoint of lowering the glass transition temperature, the content of the residues of tetracarboxylic acid anhydride having a structure represented by following General Formula (1) is more preferably 30 mol % or more when the total amount of the residues of tetracarboxylic acid anhydride is 100 mol %. The upper limit is not particularly limited but is preferably 100 mol % if possible, but the upper limit is practically about 95 mol % from the viewpoint of improving handling property of a sheet.

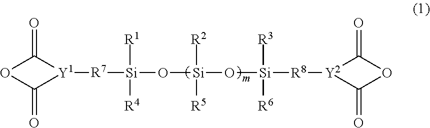

In General Formula (1), m represents an integer of 1 or more and 100 or less. R⁷ and R⁸ may be the same or different and each represent an alkylene group having 1 to 30 carbon atoms or an arylene group. The arylene group may have a substituent, the substituent is not particularly limited, and examples thereof include an alkyl group having 1 to 24 carbon atoms. R¹ to R⁶ may be the same or different and each represent an alkyl group having 1 to 30 carbon atoms, a phenyl group, or a phenoxy group. R¹ to R⁶ may be the same or different and each represent an alkyl group having 1 to 30 carbon atoms, a phenyl group, or a phenoxy group. The alkyl group having 1 to 30 carbon atoms is not particularly limited but is preferably a methyl group, an ethyl group, a propyl group, or a butyl group. The alkylene group having 1 to 30 carbon atoms is not particularly limited but is preferably a methylene group, an ethylene group, a propylene group, or a butylene group. The alkyl group and the alkylene group do not have to be a straight chain. Y¹ and Y² may be the same or different and each represent a trivalent hydrocarbon group having 1 to 20 carbon atoms.

Examples of the product corresponding to the tetracarboxylic acid anhydride represented by General Formula (1) include X-22-168AS, X-22-168A, X-22-168B, and X-22-168-P5-B manufactured by Shin-Etsu Chemical Co., Ltd. but are not limited thereto.

The polyimide resin (A) containing a siloxane unit used is naturally allowed to contain a residue of another tetracarboxylic acid anhydride in addition to the residue of tetracarboxylic acid anhydride containing a siloxane unit. Examples of such a tetracarboxylic acid anhydride include a tetracarboxylic acid anhydride such as pyromellitic anhydride (PMDA), oxydiphthalic dianhydride (ODPA), 3,3′,4,4′-benzophenonetetracarboxylic acid anhydride (BTDA), 3,3′,4,4′-biphenyltetracarboxylic acid anhydride (BPDA), 3,3′,4,4′-diphenyl sulfone tetracarboxylic acid anhydride (DSDA), 2,2′-bis[(dicarboxyphenoxy)phenyl]propane dianhydride (BSAA), 4,4′-hexafluoroisopropylidene diphthalic anhydride (6FDA), and 1,2-ethylenebis(anhydrotrimellitate) (TMEG). A plurality of these may be used. Examples of the tetracarboxylic acid anhydride that can be used are not limited thereto.

The polyimide resin (A) containing a siloxane unit used preferably contains a residue corresponding to a diamine having a structure represented by following General Formula (2) in an amount of 50 mol % or more when the total amount of diamine residues is 100 mol %. Since the siloxane unit has high flexibility, the adhesive sheet obtained using the polyimide having such a structure has a low elastic modulus and improved adhesion to the substrate. From the viewpoint of reducing the elastic modulus, the content corresponding to the diamine residue having the structure represented by following General Formula (2) is more preferably 60 mol % or more when the total amount of diamine residues is 100 mol %, and from the viewpoint of compatibility with the epoxy resin (B), the upper limit thereof is preferably 99 mol % or less, more preferably 95 mol % or less.

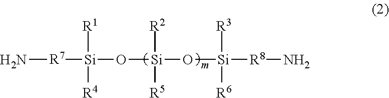

In General Formula (2), n represents an integer of 1 or more and 100 or less. R⁷ and R⁸ may be the same or different and each represent an alkylene group having 1 to 30 carbon atoms or an arylene group. The arylene group may have a substituent, the substituent is not particularly limited, and examples thereof include an alkyl group having 1 to 24 carbon atoms. R¹ to R⁶ may be the same or different and each represent an alkyl group having 1 to 30 carbon atoms, a phenyl group, or a phenoxy group. The alkyl group having 1 to 30 carbon atoms is not particularly limited but is preferably a methyl group, an ethyl group, a propyl group, or a butyl group. The alkylene group having 1 to 30 carbon atoms is not particularly limited but is preferably a methylene group, an ethylene group, a propylene group, or a butylene group. The alkyl group and the alkylene group do not have to be a straight chain.

Examples of the product corresponding to the diamine represented by General Formula (2) include X-22-161A, X-22-161B, KF8012, KF8008, and X-22-1660B-3 manufactured by Shin-Etsu Chemical Co., Ltd.

The polyimide resin (A) having a siloxane unit used preferably contains a diamine residue having a hydroxy group or a carboxy group. When the resin has a diamine residue having a hydroxy group or a carboxy group, the reaction with the epoxy resin (B) proceeds, and the toughness of the cured film after the curing reaction can be improved. The diamine having a carboxy group is particularly preferably used because the diamine has higher acidity and thus improves the dispersibility of the thermally conductive filler and improves the thermal conductivity. From the viewpoint of improving the toughness of the thermally conductive sheet, the residue of the diamine having a hydroxy group or a carboxy group is preferably contained in an amount of 1 mol % or more when the total amount of the diamine residues is 100 mol %. From the viewpoint of improving the flexibility of the adhesive sheet, the content is preferably 40 mol % or less, more preferably 30 mol % or less. Examples of the diamine residue having a hydroxy group or a carboxy group include the following.

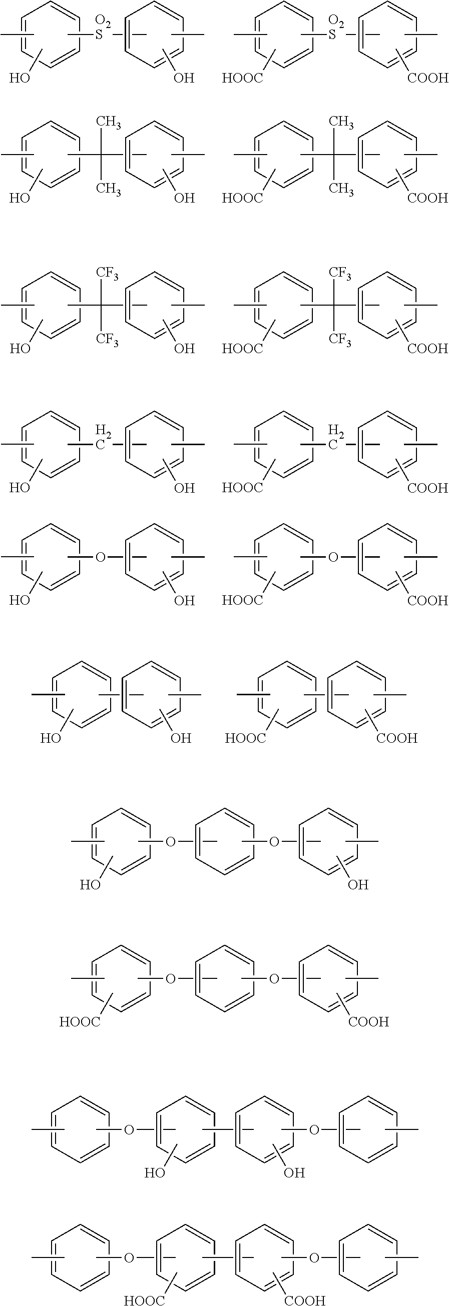

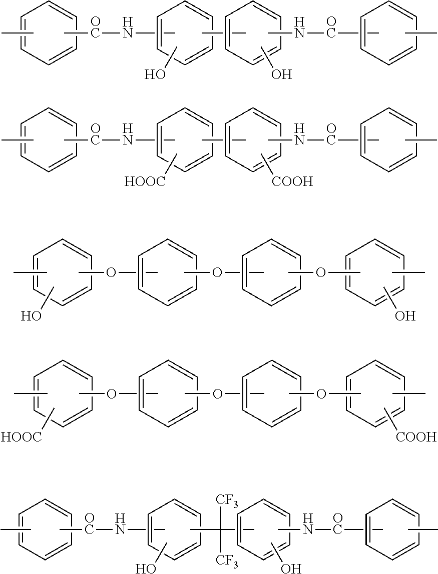

The polyimide resin (A) containing a siloxane unit used is naturally allowed to contain a residue of another diamine in addition to the residue of the diamine containing a siloxane unit. Examples of such a diamine include diamines such as diamines containing one benzene ring such as 1,4-diaminobenzene, 1,3-diaminobenzene, 2,4-diaminotoluene, and 1,4-diamino-2,5-dihalogenobenzene; diamines containing two benzene rings such as bis(4-aminophenyl) ether, bis(3-aminophenyl) ether, bis(4-aminophenyl) sulfone, bis(3-aminophenyl) sulfone, bis(4-aminophenyl)methane, bis(3-aminophenyl)methane, bis(4-aminophenyl) sulfide, bis(3-aminophenyl) sulfide, 2,2-bis(4-aminophenyl)propane, 2,2-bis(3-aminophenyl)propane, 2,2-bis(4-aminophenyl)hexafluoropropane, o-dianisidine, o-tolidine, and tolidine sulfonic acids; diamines containing three benzene rings such as 1,4-bis(4-aminophenoxy)benzene, 1,4-bis(3-aminophenoxy)benzene, 1,4-bis(4-aminophenyl)benzene, 1,4-bis(3-aminophenyl)benzene, α,α′-bis(4-aminophenyl)-1,4-diisopropylbenzene, and α,α′-bis(4-aminophenyl)-1,3-diisopropylbenzene; diamines containing four or more benzene rings such as 2,2-bis[4-(4-aminophenoxy)phenyl]propane, 2,2-bis[4-(4-aminophenoxy)phenyl]hexafluoropropane, 2,2-bis[4-(4-aminophenoxy)phenyl] sulfone, 4,4′-(4-aminophenoxy)biphenyl, 9,9-bis(4-aminophenyl)fluorene, and 5,10-bis(4-aminophenyl)anthracene. A plurality of these may be used. The other diamine that can be used are not limited thereto.

In the polyimide resin (A) containing a siloxane unit, it is preferable that the residue of tetracarboxylic acid anhydride and the residue of diamine satisfy any one or more of 1) a small number of benzene rings, 2) a large molecular weight and bulkiness, and 3) a large number of bending sites such as ether bonds. By having such a structure, the interaction between molecular chains is weakened, and the solubility of the polyimide in an organic solvent is improved.

The polyimide resin (A) containing a siloxane unit may be composed of only a resin constituted of a polyimide structural unit, or may be a copolymer having other structures as a copolymerization component in addition to the polyimide structural unit. A precursor (a polyamic acid structure) of the polyimide structural unit may also be contained. In addition, a mixture thereof may be used. Furthermore, any of these may be mixed with a polyimide represented by another structure. When another polyimide is mixed, it is preferable that 50 mol % or more of the polyimide containing a siloxane unit is contained. The type and amount of the structure used in copolymerization or mixing are preferably selected so that the desired effects will not be impaired.

The method of synthesizing the polyimide resin (A) containing a siloxane unit used is not particularly limited, and the polyimide resin can be synthesized by a known method using a diamine and a tetracarboxylic acid anhydride. For example, a method in which a tetracarboxylic acid anhydride and a diamine compound (a part of which may be substituted to be an aniline derivative) are reacted at low temperature, a method in which a tetracarboxylic acid anhydride and an alcohol are reacted to obtain a diester, and then the diester is reacted with a diamine (a part of which may be substituted to be an aniline derivative) in the presence of a condensing agent, a method in which a tetracarboxylic acid anhydride and an alcohol are reacted to obtain a diester, then the remaining two carboxy groups are converted into acid chlorides, and the resulting product is further reacted with a diamine (a part of which may be substituted to be an aniline derivative) and the like can be used to obtain a polyimide precursor, which can be used for synthesis by a known imidization method.

The resin composition contains the epoxy resin (B). When the epoxy resin is contained, the crosslinking reaction of the polyimide resin (A) containing a siloxane unit proceeds, the toughness of the adhesive sheet is improved, and the adhesive strength is improved.

The epoxy resin (B) used is preferably an epoxy resin containing a siloxane unit from the viewpoint of reducing the elastic modulus of the adhesive sheet after curing and improving the flexibility. Examples of such an epoxy resin include X-40-2695B and X-22-2046 manufactured by Shin-Etsu Chemical Co., Ltd.

The epoxy resin (B) used preferably has an epoxy equivalent of 400 g/eq or more from the viewpoint of reducing the crosslinking density of the epoxy resin after curing of the adhesive sheet to lower the glass transition temperature. Examples of such an epoxy resin include YX7105, YX7110, YX7400, YX7400N, and jER 871 manufactured by Mitsubishi Chemical Corporation and EXA-4850-150 manufactured by DIC Corporation.

The epoxy resin (B) used is preferably a crystalline epoxy resin from the viewpoint of improving the structural regularity of the adhesive sheet and improving thermal conductivity. The crystalline epoxy resin is an epoxy resin having a mesogen unit such as a biphenyl group, a naphthalene unit, an anthracene unit, a phenyl benzoate group, and a benzanilide group. Examples of products corresponding to such an epoxy resin include jER YX4000, jER YX4000H, jER YX8800, jER YL6121H, jER YL6640, jER YL6677, and jER YX7399 manufactured by Mitsubishi Chemical Corporation; NC3000, NC3000H, NC3000L, and CER-3000L manufactured by Nippon Kayaku Co., Ltd.; YSLV-80XY and YDC1312 manufactured by Nippon Steel Chemical Co., Ltd.; and HP4032, HP4032D, and HP4700 manufactured by DIC Corporation.

The epoxy resin (B) used is preferably an epoxy resin having a fluorene unit from the viewpoint of improving the dispersibility of the thermally conductive filler (D) and improving the thermal conductivity. Examples of such an epoxy resin include PG100, CG500, CG300-M2, EG200, and EG250 manufactured by Osaka Gas Chemicals Co., Ltd.

The epoxy resin (B) used is preferably a liquid epoxy resin from the viewpoint of reducing the viscosity when the thermally conductive filler (D) is dispersed. The liquid epoxy resin here shows a viscosity of 150 Pa·s or less at 25° C. and 1.013×105 N/m², and examples thereof include a bisphenol A epoxy resin, a bisphenol F epoxy resin, an alkylene oxide modified epoxy resin, and a glycidyl amine epoxy resin. Examples of products corresponding to such an epoxy resin include jER 827, jER 828, jER 806, jER 807, jER 801N, jER 802, jER 604, jER 630, and jER 630LSD manufactured by Mitsubishi Chemical Corporation; EPICLON 8405, EPICLON 8505, EPICLON 8305, EPICLON 705, and EPICLON 707 manufactured by DIC Corporation; YD-127, YD-128, PG-207N, and PG-202 manufactured by Nippon Steel Chemical Co., Ltd.; and TEPIC-PAS B26L, TEPIC-PAS B22, TEPIC-VL, TEPIC-FL, and TEPIC-UC manufactured by Nissan Chemical Corporation.

One type or a combination of two or more types of epoxy resins (B) may be used. The content of the epoxy resin (B) is preferably 0.1 parts by weight or more with respect to 100 parts by weight of the polyimide resin (A) containing a siloxane unit from the viewpoint of improving the toughness and adhesive strength of the adhesive sheet, and is preferably 15 parts by weight or less from the viewpoint of improving the flexibility of the adhesive sheet and reducing the elastic modulus at a low temperature.

The resin composition contains the siloxane diamine (C). This siloxane diamine can act as a curing agent for the epoxy resin (B). By combining the epoxy resin (B) and the siloxane diamine (C), the curing of the epoxy resin can be accelerated to complete the curing in a short time. The siloxane diamine has high flexibility of a siloxane unit and can have a low elastic modulus particularly at a low temperature after curing. In addition, since the epoxy resin (B) reacts with the siloxane diamine (C), the crosslinking density is low and flexibility is high so that the shear strain at a low temperature can be increased. The siloxane diamine (C) preferably has a structure represented by General Formula (3). From the viewpoint of reducing the elastic modulus of the adhesive sheet after curing, N is more preferably 6 or more. N is preferably 30 or less, more preferably 25 or less from the viewpoint of improving the crosslinking density and increasing the adhesive strength by the curing reaction with the epoxy resin (B). Examples of the product corresponding to the diamine represented by General Formula (3) include KF8010, X-22-161A, and X-22-9409 manufactured by Shin-Etsu Chemical Co., Ltd. The content of the siloxane diamine (C) is preferably 5% by weight or more and 20% by weight or less when the total of the polyimide resin (A) containing a siloxane unit, the epoxy resin (B), and the siloxane diamine (C) is 100% by weight. The content is preferably 5% by weight or more, more preferably 6% by weight or more from the viewpoint of accelerating the curing reaction of the epoxy resin (B). From the viewpoint of reducing the crosslinking density after the curing reaction and reducing the elastic modulus, the content is preferably 20% by weight or less, more preferably 15% by weight or less.

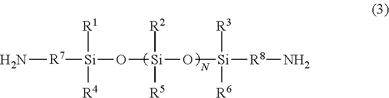

In General Formula (3), N represents an integer of 5 or more and 30 or less. R⁷ and R⁸ may be the same or different and each represent an alkylene group having 1 to 30 carbon atoms or an arylene group. R¹ to R⁶ may be the same or different and each represent an alkyl group having 1 to 30 carbon atoms, a phenyl group, or a phenoxy group.

The resin composition may further contain a curing accelerator as needed. By combining the epoxy resin (B) and the curing accelerator, the curing of the epoxy resin can be accelerated to complete the curing in a short time. As the curing accelerator, an imidazole, a polyhydric phenol, an acid anhydride, an amine, a hydrazide, a polymercaptan, a Lewis acid-amine complex, or a latent curing agent can be used.

Examples of the imidazole include Curezol 2MZ, Curezol 2PZ, Curezol 2MZ-A, and Curezol 2MZ-OK (trade names, manufactured by Shikoku Chemicals Corporation). Examples of the polyhydric phenol include SUMILITERESIN PR-HF3 and SUMILITERESIN PR-FH6 (trade names, manufactured by Sumitomo Bakelite Co., Ltd.); KAYAHARD KTG-105 and KAYAHARD NHN (trade names, manufactured by Nippon Kayaku Co., Ltd.); and PHENOLITE TD2131, PHENOLITE TD2090, PHENOLITE VH-4150, PHENOLITE KH-6021, PHENOLITE KA-1160, and PHENOLITE KA-1165 (trade names, manufactured by DIC Corporation). Examples of a latent curing accelerator include dicyandiamide latent curing accelerators, amine adduct latent curing accelerators, organic acid hydrazide latent curing accelerators, aromatic sulfonium salt latent curing accelerators, microcapsule latent curing accelerators, and photocurable latent curing accelerators.

Examples of the amine adduct latent curing accelerator include AJICURE PN-23, AJICURE PN-40, AJICURE MY-24, and AJICURE MY-H (trade names, manufactured by Ajinomoto Fine-Techno Co., Inc.); and Fujicure FXR-1030 (trade name, manufactured by FUJI KASEI CO., LTD.). Examples of the organic acid hydrazide latent curing accelerator include AJICURE VDH and AJICURE UDH (trade names, manufactured by Ajinomoto Fine-Techno Co., Inc.). Examples of the aromatic sulfonium salt latent curing accelerator include SAN-AID SI100, SAN-AID SI150, and SAN-AID SI180 (trade names, manufactured by SANSHIN CHEMICAL INDUSTRY CO., LTD.). Examples of the microcapsule latent curing accelerator include those obtained by encapsulating each of the above curing agents with a vinyl compound, a urea compound, or a thermoplastic resin. Among these, examples of the microcapsule latent curing accelerator obtained by treating the amine adduct latent curing accelerator with an isocyanate include Novacure HX-3941HP, Novacure HXA3922HP, Novacure HXA3932HP, and Novacure HXA3042HP (trade names, manufactured by ASAHI KASEI CHEMICALS CORPORATION). Examples of the photocurable latent curing accelerator include OPTOMER SP and OPTOMER CP (trade names, manufactured by ADEKA CORPORATION).

When the resin composition contains the curing accelerator, its content is preferably 0.1 parts by weight or more and 35 parts by weight or less relative to 100 parts by weight of the epoxy resin (B).

The resin composition contains the thermally conductive filler (D). The thermally conductive filler refers to inorganic particles having a thermal conductivity of 2 W/m·K or more at 25° C. The thermal conductivity can be determined by obtaining a sintered body having a thickness of about 1 mm and a porosity of 10% by volume or less and performing measurement according to JIS R 1611 (2010). Incidentally, “7.2 Measurement Method” of JIS R 1611 (2010) states “c) Bulk density: The thermal diffusivity is measured according to JIS R 1634 or the like”, but the measurement of “c) Bulk density” refers to a value determined according to JIS R 1634 (1998). Examples of the thermally conductive filler (D) include an inorganic filler such as carbon black, silica, magnesium oxide, zinc oxide, alumina, aluminum nitride, boron nitride, silicon carbide, and silicon nitride; and a metal filler of copper, aluminum, magnesium, silver, zinc, iron, lead or the like. These fillers may be used singly or in combination of a plurality of fillers. The shape of the filler is not particularly limited, and examples thereof include a perfect spherical shape, a spherical shape, a scaly shape, a flake shape, a foil piece shape, a fibrous shape, and a needle shape. From the viewpoint of containing the thermally conductive filler at a high density, it is preferable to use a perfect spherical filler.

The thermally conductive filler (D) is preferably spherical. By using a spherical filler, the viscosity of the resin composition can be reduced to increase adhesion to the base material. The spherical shape is defined as a shape in which (the average value of the maximum lengths)÷(the average value of the minimum lengths) is 1.0 or more and 1.9 or less, which is determined by observing primary particles of the thermally conductive filler with a scanning electron microscope (such as FE-SEM S-4700 (trade name) manufactured by Hitachi, Ltd.) and determining the average value of maximum lengths and the average value of minimum lengths of 50 arbitrarily selected primary particles. The “length” is determined as a distance between two parallel straight lines that are in contact with the outer edge of the image of the particle to be measured at different points.

The content of the thermally conductive filler (D) is preferably 50% by volume or more in the form of a cured film. When the content is 50% by volume or more, the thermal conductivity as a cured film is increased. It is more preferably 60% by volume or more. From the viewpoint of improving the adhesive strength, the content of the thermally conductive filler (D) is preferably 90% by volume or less, more preferably 80% by volume or less.

As a method of calculating the volume content of the filler from the cured film, the volume content is calculated by using the following thermogravimetric analysis or a method equivalent thereto. First, the cured product formed into a sheet is heated to 600 to 900° C. to decompose and volatilize the resin component, the weight of the filler contained therein is measured, and the weight of the resin is further calculated. Thereafter, the volumes are calculated by being divided by the specific gravities of the filler and the resin.

The thermally conductive filler (D) desirably contains fillers having two or more different average particle diameters. It is needless to say that two or more kinds of particles may have the same composition and different average particle diameters or may have different compositions. In addition, in the particle size distribution curve, at least 2 peaks are shown when peak division is performed, and the average particle diameter of the thermally conductive particles constituting one of the peaks is 2 μm or more, preferably 2.5 μm or more, more preferably 25 μm or more from the viewpoint of enhancing thermal conductivity. The average particle diameter of the thermally conductive particles constituting another peak is preferably 1 μm or less, preferably 0.8 μm or less. The particle size distribution of the thermally conductive filler (D) is measured by the laser diffraction/scattering method, and as a measuring instrument, SLD-3100 manufactured by Shimadzu Corporation, LA-920 manufactured by HORIBA, Ltd. or their equivalent is used. By containing two or more kinds of fillers having such different average particle diameters, the thermally conductive filler (D) can be filled at a high density, and a higher thermal conductivity can be obtained. On the other hand, from the viewpoint of improving the dispersibility of the filler, the average particle diameter of the peak of the smallest average particle diameter is preferably 0.001 μm or more, and from the viewpoint of smoothing the surface of the film as a cured film, the average particle diameter of the peak of the largest average particle diameter is preferably 100 m or less.

As described above, the method of providing 2 or more peaks when peak division is performed in the particle size distribution curve is not particularly limited, and examples thereof include a method in which a thermally conductive filler having an average particle diameter of 1.0 μm or less is blended as a material having a frequency peak of 1.0 μm or less, a thermally conductive filler having an average particle diameter of 2 μm or more is blended as a material having a frequency peak of 2 μm or more, and these are mixed to provide the resin composition.

In the particle size distribution curve, the content of the thermally conductive filler having a peak at 2 μm or more when peak division is performed is preferably 40% by volume or more, more preferably 50% by volume or more when the volume of the entire thermally conductive filler (D) is 100% by volume from the viewpoint of obtaining high thermal conductivity. In addition, the content is preferably 80% by volume or less, more preferably 70% by volume or less, from the viewpoint of obtaining high thermal conductivity by filling the thermally conductive filler at a high density.

As the thermally conductive filler, it is preferable to use alumina, boron nitride, aluminum nitride, zinc oxide, magnesium oxide, or silica. This is because the thermal conductivity of the filler is high, and the effect of increasing the thermal conductivity of the resin composition is high. In particular, it is preferable to use aluminum nitride. Since aluminum nitride has a high thermal conductivity of about 170 W/m·K as an insulating thermally conductive filler, a higher thermal conductivity can be obtained. Examples of such aluminum nitride particles include FAN-f10, FAN-f30, FAN-f50, and FAN-f80 manufactured by Furukawa Denshi Co., Ltd., and M30, M50, and M80 manufactured by MARUWA Co., Ltd.

In the thermally conductive filler (D), particles having an average particle diameter of 2 μm or more preferably have a specific surface area of 0.2 m²/g or more. When it is 0.2 m²/g or more, the interaction with the resin can be further strengthened, and the shear strain after curing of the resin composition can be increased. The specific surface area is preferably 0.2 m²/g or more, more preferably 0.25 m²/g or more. The specific surface area can be calculated by measuring the BET specific surface area by the gas adsorption method based on JIS R 1626. The mass of the thermally conductive filler is measured, gas molecules of an inert gas such as nitrogen gas and helium gas are then adsorbed, and the BET specific surface area is calculated from the monomolecular adsorption amount. The specific surface area greatly depends on the primary particle size, shape, and aggregation state of the thermally conductive filler. To increase the specific surface area, a method of crushing aggregated particles of the thermally conductive filler with a dry jet mill, a crusher or the like can be mentioned.

The resin composition may contain a surfactant as needed. The surfactant can improve the surface smoothness and adhesiveness to the base material of the cured film. The resin composition may also contain 0.5 to 10% by weight of silane coupling agents such as methylmethacryloxydimethoxysilane and 3-aminopropyltrimethoxysilane, and titanium chelating agents.

Next, a method of providing the resin composition on a support to form a laminate will be described. To process the resin composition into a laminate, for example, the resin composition can be mixed in a solvent to form a varnish, and the varnish can be applied on a support and dried to process the varnish into a sheet.

As the solvent used here, one in which the above components can be dissolved may be selected appropriately, and examples of such a solvent include ketone solvents such as acetone, methyl ethyl ketone, methyl isobutyl ketone, cyclopentanone, and cyclohexanone; ether solvents such as 1,4-dioxane, tetrahydrofuran, and diglyme; glycol ether solvents such as methyl cellosolve, ethyl cellosolve, propylene glycol monomethyl ether, propylene glycol monoethyl ether, propylene glycol monobutyl ether, and diethylene glycol methyl ethyl ether; and other solvents such as benzyl alcohol, propanol, N-methylpyrrolidone, γ-butyrolactone, ethyl acetate, and N,N-dimethylformamide. In particular, when a solvent having a boiling point of 120° C. or less under atmospheric pressure is contained, desolvation can be performed at a low temperature in a short time so that sheet formation is facilitated.

The method of forming the resin composition into a varnish is not particularly limited, but it is preferable that the polyimide resin (A) containing a siloxane unit, the epoxy resin (B), the siloxane diamine (C), the thermally conductive filler (D), and other components contained as necessary be mixed in the solvent using a propeller stirrer, a homogenizer, a kneader or the like and then mixed using a bead mill, a ball mill, a three-roll mill or the like from the viewpoint of improving the dispersibility of the thermally conductive filler (D).

Examples of the method of applying the varnish onto the support include spin coating using a spinner, spray coating, roll coating, screen printing, and a coating method in which a blade coater, a die coater, a calender coater, a meniscus coater, a bar coater, a roll coater, a comma roll coater, a gravure coater, a screen coater, a slit die coater or the like is used.

As the coating machine, a roll coater, a comma roll coater, a gravure coater, a screen coater, a slit die coater or the like can be used, but a slit die coater is preferably used because volatilization of the solvent at the time of coating is small and coatability is stabilized. The thickness of the resin composition formed into a sheet (adhesive sheet) is not particularly limited but is preferably in the range of 100 to 500 μm or less from the viewpoint of adhesion to the base material, the handling property of the adhesive sheet, and heat dissipation.

For the drying, an oven, a hot plate, infrared rays or the like can be used. The drying temperature and the drying time may be in any range within which the organic solvent can be volatilized, and the range is preferably appropriately set so that the adhesive sheet is in an uncured or semi-cured state (B stage state). Specifically, a temperature in the range of 40° C. to 120° C. is preferably maintained for 1 minute to several tens of minutes. In addition, the temperature may be increased stepwise by combining these temperatures and, for example, the heat treatment may be performed at 70° C., 80° C., and 90° C. for 1 minute each.

The support is not particularly limited, and various commercially available films such as a polyethylene terephthalate (PET) film, a polyphenylene sulfide film, and a polyimide film can be usually used.

The joint surface between the support and the resin composition may be subjected to a surface treatment with silicone, a silane coupling agent, an aluminum chelating agent, polyurea or the like to improve adhesion and peelability. In addition, the thickness of the support is not particularly limited, but is preferably 10 to 200 μm from the viewpoint of workability.

Moreover, the laminate formed into a sheet may have a protective film to protect the surface thereof. The protective film makes it possible to protect the surface of the sheet from contaminants such as dust and dirt in the atmosphere.

Examples of the protective film include a polyethylene film, a polypropylene (PP) film, and a polyester film. The protective film preferably has a small adhesive force with the laminate formed into a sheet.

Next, a method of bonding other members using the adhesive composition or the laminate processed into a sheet will be described with reference to examples. The resin composition is preferably used in the form of varnish as described above. First, a film of the resin composition is formed on one surface of a substrate or a member to be bonded using the resin composition varnish. Examples of the other member include a thin plate made of a metal material such as copper and stainless steel (SUS) and a semiconductor device (a lead frame portion thereof or the like) to be bonded thereto. Examples of the method of applying the resin composition in the form of varnish include methods such as spin coating using a spinner, spray coating, roll coating, and screen printing. In addition, the film thickness applied varies depending on the application technique, the solid content concentration and the viscosity of the resin composition and the like, but usually, it is preferable to apply so that the film thickness after drying is 50 μm or more and 400 μm or less. Next, the substrate applied with the adhesive composition varnish is dried to obtain an adhesive composition coating film. For drying, an oven, a hot plate, infrared rays or the like can be used. The drying temperature and the drying time may be in a range in which the organic solvent can be volatilized, and it is preferable to appropriately set a range where the adhesive resin composition coating film is in an uncured or semi-cured state. Specifically, the drying is preferably performed in the range of 50 to 150° C. for 1 minute to several hours.

On the other hand, when the laminate processed into a sheet is used, the protective film is peeled off when the laminate has the protective film, and the laminate and another member are opposed to each other and bonded to each other by pressure bonding. The pressure bonding may be performed while rising the temperature, which can be performed by a heat press treatment, a heat lamination treatment, a heat vacuum lamination treatment or the like. When the temperature is risen, the bonding temperature is preferably 40° C. or more from the viewpoint of adhesion and embeddability to the substrate. In addition, when the temperature increases at the time of bonding, the time for curing the resin composition is shortened and workability is deteriorated so that the bonding temperature is preferably 250° C. or less. When the laminate processed into a sheet is provided with the support, the support may be peeled off before bonding, or may be peeled off at any point in the thermocompression bonding or after the thermocompression bonding.

The substrate thus obtained on which the film of the resin composition is formed is thermocompression-bonded to a substrate or another member. The thermocompression bonding temperature is preferably in the temperature range of 100 to 400° C. The pressure during pressure bonding is preferably in the range of 0.01 to 10 MPa. The time is preferably one second to several hours. In addition, it is preferable to form a cured product at the time of thermocompression bonding, and as an example, a heat treatment is performed at 100° C. and a pressure of 0.5 MPa for 24 hours.

On the other hand, after thermocompression bonding, a temperature of 120° C. to 400° C. may be applied to form a cured product. There are found suitable temperature conditions for the heating treatment, and the heating treatment is carried out for 5 minutes to 24 hours while rising the temperature stepwise or while rising the temperature continuously within a certain temperature range. As an example, the heat treatment is performed at 130° C. and 200° C. for 30 minutes each. Alternatively, examples thereof include a method of linearly increasing the temperature over 1 hour from room temperature up to 250° C. At this time, the heating temperature is preferably 100° C. or more and 300° C. or less, more preferably 120° C. or more and 200° C. or less.

In the product thus obtained, the sheet-shaped resin composition or the cured film can reduce the contact thermal resistance at the interface of the base material and enables cooling to a lower temperature.

At this time, to reduce the thermal resistance of the sheet, the thermal conductivity of the adhesive sheet at −70° C. is preferably 0.8 W/m·K or more, more preferably 1.0 W/m·K or more.

The elastic modulus of the sheet-shaped resin composition or the cured film at −50° C. is preferably 1 MPa or more and 100 MPa or less, and the elastic modulus at −70° C. is also preferably 1 MPa or more and 100 MPa or less. These are preferably 1 MPa or more, more preferably 2 MPa or more from the viewpoint of improving the adhesive strength at −50° C. From the viewpoint of reducing the thermal stress of the laminate at a low temperature to prevent peeling and cracking of the sheet-shaped resin composition or the cured film, the elastic modulus is preferably 100 MPa or less, more preferably 50 MPa or less. The elastic modulus of the cured film is determined by the method described in the Examples section.

The sheet-shaped resin composition or the cured film preferably has a shear strain of 2 or more and 10 or less at −50° C. The shear strain is a value obtained by dividing the amount of strain until rupture by the thickness of the adhesive sheet when a test is conducted in accordance with JIS K 6850 (Determination of tensile lap-shear strength of rigid-to-rigid bonded assemblies). The value is preferably two or more, more preferably three or more from the viewpoint of suppressing peeling and cracking following a dimensional change due to a temperature change of the bonded base material. From the viewpoint of suppressing the dimensional change of the sheet-shaped resin composition or the cured film, the value is preferably 10 or less, more preferably 8 or less. The above shear strain is determined by the method described in the Examples section.

The thickness of the cured film can be arbitrarily set but is preferably 100 μm or more and 500 μm or less.

Next, the application of the resin composition and the laminate processed into a sheet will be described by way of an example, but the application of the resin composition and the laminate processed into a sheet is not limited to the following.

The resin composition and the laminate processed into a sheet can be widely used as an adhesive sheet of a semiconductor device, and are particularly suitably used in plasma processing equipment used in a semiconductor manufacturing process. In the plasma processing equipment used in the semiconductor manufacturing process, etching or the like is performed as follows: the substrate to be processed such as a semiconductor wafer is placed on an electrostatic chuck provided in a processing chamber, and a high frequency voltage is applied to the processing chamber under a vacuum environment to generate plasma. The electrostatic chuck is a laminate obtained by joining a ceramic plate in which a heater electrode and an electrostatic electrode are built, and a cooling plate in which a refrigerant flow path is formed, with an adhesive sheet. In recent years, semiconductor processing accuracy has increased, and etching processing is performed at a low temperature of −30° C. or less in processing for creating a high aspect ratio. At this time, since it is necessary to cool the ceramic plate by reducing the temperature to −30° C. or less with the cooling plate, the thermal resistance of the interface can be reduced and the ceramic plate can be efficiently cooled with the adhesive sheet. The adhesive sheet is attached to the cooling plate, or the varnish of the resin composition is applied and dried to form an adhesive layer. Thereafter, the ceramic plate is subjected to pressure bonding or thermocompression bonding to obtain an electrostatic chuck that does not show peeling or cracking even at a low temperature.

### EXAMPLES

Hereinafter, our compositions, methods and devices will be specifically described with reference to examples, but this disclosure is not to be construed as being limited thereto. The details of the raw materials indicated by abbreviations in each example are shown below.

### Raw Material of Polyimide

ODPA: 4,4′-oxydiphthalic dianhydride (manufactured by Manac Incorporated)
X-22-168AS: both-end maleic anhydride-modified polysiloxane (manufactured by Shin-Etsu Chemical Co., Ltd.)
X-22-168A: both-end maleic anhydride-modified polysiloxane (manufactured by Shin-Etsu Chemical Co., Ltd.)
BAHF: 2,2-bis(3-amino-4-hydroxyphenyl)hexafluoropropane (manufactured by AZ Electronic Materials)
X-22-161A: both-end amine-modified polysiloxane (manufactured by Shin-Etsu Chemical Co., Ltd.)
X-22-161B: both-end amine-modified polysiloxane (manufactured by Shin-Etsu Chemical Co., Ltd.).

### Epoxy Resin

YX7400N: rubber-elastic liquid epoxy resin (manufactured by Mitsubishi Chemical Corporation)

### Curing Agent

LP7100: bis(3-aminopropyl)tetramethyldisiloxane (manufactured by Shin-Etsu Chemical Co., Ltd.)
KF8010: diaminopolysiloxane (manufactured by Shin-Etsu Chemical Co., Ltd.)
X-22-161A: diaminopolysiloxane (manufactured by Shin-Etsu Chemical Co., Ltd.)
X-22-161B: diaminopolysiloxane (manufactured by Shin-Etsu Chemical Co., Ltd.)
3,3′-DDS: 3,3′-diaminodiphenyl sulfone (manufactured by Wakayama Seika Kogyo Co., Ltd.).

### Spherical Thermally Conductive Filler

DAW45: alumina particles (average particle diameter: 45 μm, specific surface area: 0.21 m²/g, thermal conductivity: 26 W/m·K) (manufactured by Denka Co., Ltd.)
AA3: alumina particles (average particle diameter: 3 μm, specific surface area: 0.60 m²/g, thermal conductivity: 20 W/m·K) (manufactured by Sumitomo Chemical Co., Ltd.)
AA04: alumina particles (average particle diameter: 0.4 μm, specific surface area: 4.10 m²/g, thermal conductivity: 20 W/m·K) (manufactured by Sumitomo Chemical Co., Ltd.)
FAN-30: aluminum nitride particles (average particle diameter: 30 μm, specific surface area: 0.15 m²/g, thermal conductivity: 170 W/m·K) (manufactured by Furukawa Denshi Co., Ltd.)
   Each of the above spherical thermally conductive fillers was confirmed to be spherical by observation of primary particles with a scanning electron microscope.

### Flake Thermally Conductive Filler

UHP-2: boron nitride particles (average particle diameter: 10 μm, specific surface area: 3.8 m²/g, thermal conductivity: 80 W/m·K) (manufactured by Showa Denko K. K.).

### Curing Accelerator

2P4MZ: 2-phenyl-4-methylimidazole.

### Solvent

Triglyme: triethylene glycol dimethyl ether.
   Evaluation methods in examples and comparative examples will be indicated below.

### Weight-Average Molecular Weight of Polyimide

A solution having a solid content concentration of 0.1% by weight obtained by dissolving the polyimide in N-methyl-2-pyrrolidone (hereinafter referred to as NMP) was used to calculate the polystyrene conversion weight-average molecular weight using a GPC apparatus Waters 2690 (Waters Corporation) having the following configuration. The GPC measurement conditions were as follows: a moving bed was NMP in which LiCl and phosphoric acid were dissolved at concentrations of 0.05 mol/1 each, and the development rate was 0.4 μml/min.
Detector: Waters 996
System controller: Waters 2690
Column oven: Waters HTR-B
Thermo controller: Waters TCM
Column: TOSOH grard comn
Column: THSOH TSK-GEL α-4000
Column: TOSOH TSK-GEL α-2500.

### Imidization Ratio of Polyimide

First, the infrared absorption spectrum of the polymer was measured to confirm the presence of absorption peaks (near 1780 cm-1 and near 1377 cm⁻¹) of the imide structure attributed to the polyimide. Next, the polymer was subjected to a heat treatment at 350° C. for 1 hour, an infrared spectrum was measured again, and then peak intensities near 1,377 cm⁻¹ before the heat treatment and after the heat treatment were compared. Assuming that the imidization ratio of the polymer after the heat treatment was 100%, the imidization ratio of the polymer before the heat treatment was determined.

### Average Particle Diameter of Thermally Conductive Filler

The filler was dispersed in methanol, and the particle size distribution was measured by the laser diffraction/scattering method using LA-920 manufactured by HORIBA, Ltd. The particle diameter D50 at which the cumulative particle diameter distribution from the small particle diameter side based on the volume was 50% was defined as the average particle diameter.

### Specific Surface Area of Thermally Conductive Filler

The specific surface area was measured by the single point method by the BET flow method using a fully automatic specific surface area measuring apparatus Macsorb manufactured by Mountech Co., Ltd.

### Content of Thermally Conductive Filler

The weight of each component was divided by the specific gravity to calculate the volume, and the content of the thermally conductive filler based on 100 parts by volume of the total of the polyimide resin, the epoxy resin, the siloxane diamine, and the thermally conductive filler was calculated.

### Thermal Conductivity

The resin composition was applied on a PET film having a thickness of 38 μm using a comma roll coater so that the film thickness of the cured film was 250 μm, dried at 100° C. for 30 minutes, and then thermally cured at 180° C. for 4 hours to obtain a sheet-shaped laminate. Thereafter, the PET film was peeled off, and the thermal diffusivity of the cured film was measured using a laser flash method thermal diffusivity measuring apparatus LFA447 manufactured by NETZSCH Japan K.K. The specific gravity of the cured film was measured by the Archimedes method, and the specific heat of the adhesive sheet was measured by the DSC method. From the obtained measured values, the thermal conductivity was calculated by the calculation formula of thermal diffusivity (m²/s)×specific gravity (kg/m³)×specific heat (J/kg·K).

### Elastic Modulus

After peeling off the PET film of the sheet-shaped laminate obtained by the above method, the sheet was cut into a shape of 30 mm×5 mm, and the elastic modulus of the film was measured using a dynamic viscoelasticity measuring apparatus DVA-200 manufactured by IT Measurement Control Co., Ltd. The storage elastic modulus at each temperature in the range from −100° C. to 300° C. was measured under the measurement conditions of a temperature rise rate of 5° C./min and a measurement frequency of 1 Hz, and the elastic modulus at −50° C. was determined.

### Shear Adhesive Strength/Shear Strain

The resin composition was applied on a PET film having a thickness of 38 μm using a comma roll coater so that the film thickness of the cured film was 250 μm and dried at 100° C. for 30 minutes to obtain a laminate before curing. The laminate before curing was cut into 12.5×25 mm, laminated on an aluminum plate having a size of 100×25 mm and a thickness of 1.6 mm under the conditions of 60° C. and 0.1 MPa, the PET film was peeled off, an aluminum plate having a size of 100×25 mm and a thickness of 1.6 mm was then laminated, and the product was heated and pressed at 180° C. and 0.5 MPa for 1 hour. Thereafter, in accordance with JIS K 6850, a shear test was performed at a tensile speed of 2 mm/min in an atmosphere at −50° C. using a universal tester AGX-V manufactured by Shimadzu Corporation, and the shear adhesive strength as the stress at the time of rupture and the shear strain were measured.

### Cooling/Heating Cycle Reliability Test

The resin composition was applied on a PET film having a thickness of 38 μm using a comma roll coater so that the film thickness of the cured film was 250 μm and dried at 100° C. for 30 minutes to obtain a laminate before curing. The laminate before curing was cut into 150 mm, laminated on an aluminum plate having a diameter of 100 mm and a thickness of 3 mm under the conditions of 60° C. and 0.1 MPa, the PET film was peeled off, an alumina substrate having a diameter of 100 mm and a thickness of 3 mm was then laminated, and the product was heated and pressed at 120° C. and 0.5 MPa for 24 hours. The laminate thus obtained was observed with an ultrasonic flaw detector FS 300 manufactured by Hitachi Power Solutions Co., Ltd. to determine whether there was a peeled portion. Thereafter, using a thermal shock testing machine, the treatment at −65° C. for 30 minutes and at 100° C. for 30 minutes was defined as one cycle, and the peeling state and whether there was a crack in the alumina substrate were observed in appearance at the time of 250 cycles, 500 cycles, and 1,000 cycles. When peeling or cracking occurred immediately after the laminate was produced, the phenomenon occurred was recorded in the tables, and when peeling or cracking was observed in the cycle test, the number of cycles in which peeling or cracking was first found at the time of observation was recorded.

### Example 1

A stirrer, a thermometer, a nitrogen introducing tube, and a dropping funnel were set to a 300-ml four-necked flask, and 78.53 g of triglyme and 40.40 g of X-22-168AS were charged thereto under a nitrogen atmosphere, and stirred and dissolved at 60° C. Thereafter, while stirring at 60° C., 7.33 g of BAHF and 30.80 g of X-22-161A were added thereto, and the mixture was stirred for 1 hour. Thereafter, the mixture was heated to 180° C., stirred for 3 hours, and then cooled to room temperature to obtain a polyimide solution A (solid content concentration: 50.0% by weight). The weight-average molecular weight of the polyimide was measured and found to be 28,600, and the imidization ratio was measured and found to be 99%.

To 10.8 g of the polyimide solution A (solid content: 5.4 g) obtained by the above method, 0.3 g of YX7400N, 0.3 g of KF8010, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 2

A stirrer, a thermometer, a nitrogen introducing tube, and a dropping funnel were set to a 300-ml four-necked flask, and 87.92 g of triglyme and 40.40 g of X-22-168AS were charged thereto under a nitrogen atmosphere, and stirred and dissolved at 60° C. Thereafter, while stirring at 60° C., 4.40 g of BAHF and 43.12 g of X-22-161A were added thereto, and the mixture was stirred for 1 hour. Thereafter, the mixture was heated to 180° C., stirred for 3 hours, and then cooled to room temperature to obtain a polyimide solution B (solid content concentration: 50.0% by weight). The weight-average molecular weight of the polyimide was measured and found to be 19,400, and the imidization ratio was measured and found to be 99%. Respective components shown in Table 2 were mixed with 10.8 g of the polyimide B (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 3

A stirrer, a thermometer, a nitrogen introducing tube, and a dropping funnel were set to a 300-ml four-necked flask, and 72.98 g of triglyme and 30.30 g of X-22-168AS were charged thereto under a nitrogen atmosphere, and stirred and dissolved at 60° C. Thereafter, while stirring at 60° C., 1.10 g of BAHF and 41.58 g of X-22-161A were added thereto, and the mixture was stirred for 1 hour. Thereafter, the mixture was heated to 180° C., stirred for 3 hours, and then cooled to room temperature to obtain a polyimide solution C (solid content concentration: 50.0% by weight). The weight-average molecular weight of the polyimide was measured and found to be 18,800, and the imidization ratio was measured and found to be 99%. Respective components shown in Table 2 were mixed with 10.8 g of the polyimide C (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 4

A stirrer, a thermometer, a nitrogen introducing tube, and a dropping funnel were set to a 300-ml four-necked flask, and 74.93 g of triglyme and 20.20 g of X-22-168AS were charged thereto under a nitrogen atmosphere, and stirred and dissolved at 60° C. Thereafter, while stirring at 60° C., 0.73 g of BAHF and 54.00 g of X-22-161B were added thereto, and the mixture was stirred for 1 hour. Thereafter, the mixture was heated to 180° C., stirred for 3 hours, and then cooled to room temperature to obtain a polyimide solution D (solid content concentration: 50.0% by weight). The weight-average molecular weight of the polyimide was measured and found to be 19,200, and the imidization ratio was measured and found to be 99%. Respective components shown in Table 2 were mixed with 10.8 g of the polyimide D (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 5

A stirrer, a thermometer, a nitrogen introducing tube, and a dropping funnel were set to a 300-ml four-necked flask, and 68.45 g of triglyme and 40.00 g of X-22-168A were charged thereto under a nitrogen atmosphere, and stirred and dissolved at 60° C. Thereafter, while stirring at 60° C., 0.73 g of BAHF and 27.72 g of X-22-161A were added thereto, and the mixture was stirred for 1 hour. Thereafter, the mixture was heated to 180° C., stirred for 3 hours, and then cooled to room temperature to obtain a polyimide solution E (solid content concentration: 50.0% by weight). The weight-average molecular weight of the polyimide was measured and found to be 16,520, and the imidization ratio was measured and found to be 99%. Respective components shown in Table 2 were mixed with 10.8 g of the polyimide E (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 6

A stirrer, a thermometer, a nitrogen introducing tube, and a dropping funnel were set to a 300-ml four-necked flask, and 83.31 g of triglyme, 20.20 g of X-22-168A, and 6.20 g of ODPA were charged thereto under a nitrogen atmosphere, and stirred and dissolved at 60° C. Thereafter, while stirring at 60° C., 1.47 g of BAHF and 55.44 g of X-22-161A were added thereto, and the mixture was stirred for 1 hour. Thereafter, the mixture was heated to 180° C., stirred for 3 hours, and then cooled to room temperature to obtain a polyimide solution F (solid content concentration: 50.0% by weight). The weight-average molecular weight of the polyimide was measured and found to be 23,900, and the imidization ratio was measured and found to be 99%. Respective components shown in Table 2 were mixed with 10.8 g of the polyimide F (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 7

A stirrer, a thermometer, a nitrogen introducing tube, and a dropping funnel were set to a 300-ml four-necked flask, and 72.11 g of triglyme, 4.04 g of X-22-168A, and 11.17 g of ODPA were charged thereto under a nitrogen atmosphere, and stirred and dissolved at 60° C. Thereafter, while stirring at 60° C., 1.47 g of BAHF and 55.44 g of X-22-161A were added thereto, and the mixture was stirred for 1 hour. Thereafter, the mixture was heated to 180° C., stirred for 3 hours, and then cooled to room temperature to obtain a polyimide solution G (solid content concentration: 50.0% by weight). The weight-average molecular weight of the polyimide was measured and found to be 30,100, and the imidization ratio was measured and found to be 99%. Respective components shown in Table 2 were mixed with 10.8 g of the polyimide G (solid content: 5.4 g) thus obtained in the same manner as in Example 1 to obtain a resin composition. The thermal conductivity, elastic modulus, shear adhesive strength, shear strain, and cooling/heating cycle reliability test of the obtained resin composition were measured by the above methods.

### Example 8

To 10.8 g of the polyimide solution C (solid content: 5.4 g) obtained in Example 3, 0.5 g of YX7400N, 0.1 g of LP7100, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 9

To 10.8 g of the polyimide solution C (solid content: 5.4 g) obtained in Example 3, 0.25 g of YX7400N, 0.35 g of X-22-161A, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 10

To 10.8 g of the polyimide solution C (solid content: 5.4 g) obtained in Example 3, 0.2 g of YX7400N, 0.4 g of X-22-161B, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 11

To 8.4 g of the polyimide solution C (solid content: 4.2 g) obtained in Example 3, 0.9 g of YX7400N, 0.9 g of KF8010, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 12

To 6.0 g of the polyimide solution C (solid content: 3.0 g) obtained in Example 3, 1.5 g of YX7400N, 1.5 g of KF8010, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 13

A viscous liquid resin composition was obtained in the same manner as in Example 3 except that 18 g of AA3 was changed to 18 g of DAW45. The thermal conductivity, elastic modulus, shear adhesive strength, shear strain, and cooling/heating cycle reliability test of the obtained resin composition were measured by the above methods.

### Example 14

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. AA3 (22 g) and AA04 (15 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 15

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. FAN-30 (16.5 g) and AA04 (10 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 16

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. AA04 (30 g) was added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 17

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. AA3 (30 g) was added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 18

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. DAW45 (30 g) was added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 19

To 10.8 g of the polyimide solution C (solid content: 5.4 g) obtained in Example 3, 0.3 g of YX7400N, 0.3 g of KF8010, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 20

To 10.8 g of the polyimide solution C (solid content: 5.4 g) obtained in Example 3 were added 0.3 g of YX7400N, 0.3 g of KF8010, and 0.02 g of 2P4MZ, and the mixture was mixed and stirred. FAN-30 was ground in a mortar and crushed to have a specific surface area of 0.26 m²/g. FAN-30 (16.5 g) thus crushed and AA04 (10 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 21

To 10.8 g of the polyimide solution C (solid content: 5.4 g) obtained in Example 3 were added 0.3 g of YX7400N, 0.3 g of KF8010, and 0.02 g of 2P4MZ, and the mixture was mixed and stirred. FAN-30 was ground in a mortar and crushed to have a specific surface area of 0.36 m²/g. FAN-30 (16.5 g) thus crushed and AA04 (10 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Example 22

To 10.8 g of the polyimide solution C (solid content: 5.4 g) obtained in Example 3 were added 0.3 g of YX7400N, 0.3 g of KF8010, and 0.02 g of 2P4MZ, and the mixture was mixed and stirred. FAN-30 was ground in a mortar and crushed to have a specific surface area of 0.51 m²/g. FAN-30 (16.5 g) thus crushed and AA04 (10 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Comparative Example 1

To 10.8 g of the polyimide solution C (solid content: 5.4 g) obtained in Example 3, 0.35 g of YX7400N, 0.25 g of 3,3′-DDS, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Comparative Example 2

To 10.8 g of the polyimide solution C (solid content: 5.4 g) obtained in Example 3, 0.6 g of YX7400N and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

### Comparative Example 3

A stirrer, a thermometer, a nitrogen introducing tube, and a dropping funnel were set to a 300-ml four-necked flask, and 135.3 g of triglyme and 62.40 g of ODPA were charged thereto under a nitrogen atmosphere, and stirred and dissolved at 60° C. Thereafter, while stirring at 60° C., 73.25 g of BAHF was added thereto, and the mixture was stirred for 1 hour. Thereafter, the mixture was heated to 180° C., stirred for 3 hours, and then cooled to room temperature to obtain a polyimide solution H (solid content concentration: 50.0% by weight). The weight-average molecular weight of the polyimide was measured and found to be 38,500, and the imidization ratio was measured and found to be 99%.

To 10.8 g of the polyimide solution H (solid content: 5.4 g) obtained by the above method, 0.3 g of YX7400N, 0.3 g of KF8010, and 0.02 g of 2P4MZ were added, and the mixture was mixed and stirred. AA3 (18 g) and AA04 (12 g) were added thereto, and the mixture was repeatedly kneaded 5 times with a triple roll mill to obtain a viscous liquid resin composition. The thermal conductivity, elastic modulus, shear adhesive strength, shear strain, and cooling/heating cycle reliability test of the obtained resin composition were measured by the above methods.

TABLE 1

| | | Polyimide | Polyimide | Polyimide | Polyimide | Polyimide | Polyimide | Polyimide | Polyimide |
|---|---|---|---|---|---|---|---|---|---|
| Item | | A | B | C | D | E | F | G | H |
| Acid anhydride | ODPA | | | | | | 50 | 90 | 100 |
| monomer | X-22-168AS | 100 | 100 | 100 | 100 | | 50 | 10 | |
| (mol %) | X-22-168A | | | | | 100 | | | |
| Diamine | BAHF | 50 | 30 | 10 | 10 | 10 | 10 | 10 | 100 |
| monomer | X-22-161A | 50 | 70 | 90 | | 90 | 90 | 90 | |
| (mol %) | X-22-161B | | | | 90 | | | | |
| Properties | Imidization | 99 | 99 | 99 | 99 | 99 | 99 | 99 | 99 |
| | ratio (%) | | | | | | | | |
| | Weight-average | 28600 | 19400 | 18800 | 19200 | 16520 | 23900 | 30100 | 38500 |
| | molecular weight | | | | | | | | |

TABLE 2

| | | Average | Specific | | | | |
|---|---|---|---|---|---|---|---|
| | | particle | surface | | | | |
| | | diameter | area | Example | Example | Example | Example |
| Item | | (?m) | (m²/g) | 1 | 2 | 3 | 4 |
| Polyimide | Polyimide A | | | 5.4 | | | |
| resin (g) | Polyimide B | | | | 5.4 | | |
| | Polyimide C | | | | | 5.4 | |
| | Polyimide D | | | | | | 5.4 |
| | Polyimide E | | | | | | |
| | Polyimide F | | | | | | |
| | Polyimide G | | | | | | |
| | Polyimide H | | | | | | |
| Epoxy resin (g) | YX7400N | | | 0.3 | 0.3 | 0.3 | 0.3 |
| Curing agent (g) | LP7100 | | | | | | |
| | KF8010 | | | 0.3 | 0.3 | 0.3 | 0.3 |
| | X-22-161A | | | | | | |
| | X-22-161B | | | | | | |
| | 3,3′-DDS | | | | | | |
| Thermally | DAW45 | 45 | 0.21 | | | | |
| conductive | FAN-30 | 30 | 0.15 | | | | |
| filler (g) | | 30 | 0.26 | | | | |
| | | 30 | 0.36 | | | | |
| | | 29 | 0.51 | | | | |
| | AA3 | 3 | 0.60 | 18 | 18 | 18 | 18 |
| | AA04 | 0.4 | 4.1 | 12 | 12 | 12 | 12 |
| Flake | UHP-2 | 10 | 3.8 | | | | |
| thermally | | | | | | | |
| conductive | | | | | | | |
| filler (g) | | | | | | | |
| Curing | 2P4MZ | | | 0.02 | 0.02 | 0.02 | 0.02 |
| accelerator | | | | | | | |
| (g) | | | | | | | |

| | | Example | Example | Example | Example | Example |
|---|---|---|---|---|---|---|
| Item | | 5 | 6 | 7 | 8 | 9 |
| Polyimide | Polyimide A | | | | | |
| resin (g) | Polyimide B | | | | | |
| | Polyimide C | | | | 5.4 | 5.4 |
| | Polyimide D | | | | | |
| | Polyimide E | 5.4 | | | | |
| | Polyimide F | | 5.4 | | | |
| | Polyimide G | | | 5.4 | | |
| | Polyimide H | | | | | |
| Epoxy resin (g) | YX7400N | 0.3 | 0.3 | 0.3 | 0.5 | 0.25 |
| Curing agent (g) | LP7100 | | | | 0.1 | |
| | KF8010 | 0.3 | 0.3 | 0.3 | | |
| | X-22-161A | | | | | 0.35 |
| | X-22-161B | | | | | |
| | 3,3′-DDS | | | | | |
| Thermally | DAW45 | | | | | |
| conductive | FAN-30 | | | | | |
| filler (g) | AA3 | 18 | 18 | 18 | 18 | 18 |
| | AA04 | 12 | 12 | 12 | 12 | 12 |
| Flake | UHP-2 | | | | | |
| thermally | | | | | | |
| conductive | | | | | | |
| filler (g) | | | | | | |
| Curing | 2P4MZ | 0.02 | 0.02 | 0.02 | 0.02 | 0.02 |
| accelerator | | | | | | |
| (g) | | | | | | |

TABLE 3

| | | Average | Specific | | | | |
|---|---|---|---|---|---|---|---|
| | | particle | surface | | | | |
| | | diameter | area | Example | Example | Example | Example |
| Item | | (μm) | (m²/g) | 10 | 11 | 12 | 13 |
| Polyimide | Polyimide A | | | | | | |
| resin (g) | Polyimide B | | | | | | |
| | Polyimide C | | | 5.4 | 4.2 | 3 | 5.4 |
| | Polyimide D | | | | | | |
| | Polyimide E | | | | | | |
| | Polyimide F | | | | | | |
| | Polyimide G | | | | | | |
| | Polyimide H | | | | | | |
| Epoxy resin (g) | YX7400N | | | 0.2 | 0.9 | 1.5 | 0.3 |
| Curing agent (g) | LP7100 | | | | | | |
| | KF8010 | | | | 0.9 | 1.5 | 0.3 |
| | X-22-161A | | | | | | |
| | X-22-161B | | | 0.4 | | | |
| | 3,3′-DDS | | | | | | |
| Spherical | DAW45 | 45 | 0.21 | | | | 18 |
| thermally | FAN-30 | 30 | 0.15 | | | | |
| conductive | | 30 | 0.26 | | | | |
| filler (g) | | 29 | 0.36 | | | | |
| | | 29 | 0.51 | | | | |
| | AA3 | 3 | 0.60 | 18 | 18 | 18 | |
| | AA04 | 0.4 | 4.1 | 12 | 12 | 12 | 12 |
| Flake | UHP-2 | 10 | 3.8 | | | | |
| thermally | | | | | | | |
| conductive | | | | | | | |
| filler (g) | | | | | | | |
| Curing | 2P4MZ | | | 0.02 | 0.02 | 0.02 | 0.02 |
| accelerator | | | | | | | |
| (g) | | | | | | | |

| | | Example | Example | Example | Example | Example |
|---|---|---|---|---|---|---|
| Item | | 14 | 15 | 16 | 17 | 18 |
| Polyimide | Polyimide A | | | | | |
| resin (g) | Polyimide B | | | | | |
| | Polyimide C | 5.4 | 5.4 | 5.4 | 5.4 | 5.4 |
| | Polyimide D | | | | | |
| | Polyimide E | | | | | |
| | Polyimide F | | | | | |
| | Polyimide G | | | | | |
| | Polyimide H | | | | | |
| Epoxy resin (g) | YX7400N | 0.3 | 0.3 | 0.3 | 0.3 | 0.3 |
| Curing agent (g) | LP7100 | | | | | |
| | KF8010 | 0.3 | 0.3 | 0.3 | 0.3 | 0.3 |
| | X-22-161A | | | | | |
| | X-22-161B | | | | | |
| | 3,3′-DDS | | | | | |
| Spherical | DAW45 | | | | | 30 |
| thermally | FAN-30 | | 16.5 | | | |
| conductive | AA3 | 22 | | | 30 | |
| filler (g) | AA04 | 15 | 10 | 30 | | |
| Flake | UHP-2 | | | | | |
| thermally | | | | | | |
| conductive | | | | | | |
| filler (g) | | | | | | |
| Curing | 2P4MZ | 0.02 | 0.02 | 0.02 | 0.02 | 0.02 |
| accelerator | | | | | | |
| (g) | | | | | | |

TABLE 4

| | | Average | Specific | | | | | | | |
|---|---|---|---|---|---|---|---|---|---|---|
| | | particle | surface | | | | | | | |
| | | diameter | area | Example | Example | Example | Example | Comparative | Comparative | Comparative |
| Item | | (μm) | (m²/g) | 19 | 20 | 21 | 22 | Example 1 | Example 2 | Example 3 |
| Polyimide | Polyimide A | | | | | | | | | |
| resin (g) | Polyimide B | | | | | | | | | |
| | Polyimide C | | | 5.4 | 5.4 | 5.4 | 5.4 | 5.4 | 5.4 | |
| | Polyimide D | | | | | | | | | |
| | Polyimide E | | | | | | | | | |
| | Polyimide F | | | | | | | | | |
| | Polyimide G | | | | | | | | | |
| | Polyimide H | | | | | | | | | 5.4 |
| Epoxy resin (g) | YX7400N | | | 0.3 | 0.3 | 0.3 | 0.3 | 0.35 | 0.6 | 0.3 |
| Curing agent (g) | LP7100 | | | | | | | | | |
| | KF8010 | | | 0.3 | 0.3 | 0.3 | 0.3 | | | 0.3 |
| | X-22-161A | | | | | | | | | |
| | X-22-161B | | | | | | | | | |
| | 3,3′-DDS | | | | | | | 0.25 | | |
| Thermally | DAW45 | 45 | 0.21 | | | | | | | |
| conductive | FAN-30 | 30 | 0.15 | | | | | | | |
| filler (g) | | 30 | 0.26 | | 16.5 | | | | | |
| | | 29 | 0.36 | | | 16.5 | | | | |
| | | 29 | 0.51 | | | | 16.5 | | | |
| | AA3 | 3 | 0.60 | 14 | | | | 18 | 18 | 18 |
| | AA04 | 0.4 | 4.1 | 12 | 10 | 10 | 10 | 12 | 12 | 12 |
| Flake | UHP-2 | 10 | 3.8 | 2.2 | | | | | | |
| thermally | | | | | | | | | | |
| conductive | | | | | | | | | | |
| filler (g) | | | | | | | | | | |
| Curing | 2P4MZ | | | 0.02 | 0.02 | 0.02 | 0.02 | 0.02 | 0.02 | 0.02 |
| accelerator | | | | | | | | | | |
| (g) | | | | | | | | | | |

TABLE 5

| | Example | Example | Example | Example | Example | Example | Example | Example | Example |
|---|---|---|---|---|---|---|---|---|---|
| Item | 1 | 2 | 3 | 4 | 5 | 6 | 7 | 8 | 9 |
| Thermal conductivity | 1.4 | 1.3 | 1.2 | 1.2 | 1.2 | 1.2 | 1.2 | 1.2 | 1.2 |
| (W/mK) | | | | | | | | | |
| Elastic modulus at −50° C. | 150 | 100 | 8 | 1 | 0.8 | 75 | 135 | 80 | 4 |
| (MPa) | | | | | | | | | |
| Shear adhesive strength | 4.0 | 3.2 | 2.6 | 1.2 | 1.0 | 2.9 | 2.8 | 2.6 | 2.0 |
| at −50° C. (MPa) | | | | | | | | | |
| Shear strain at −50° C. | 1.5 | 2.1 | 3.5 | 2.2 | 2.0 | 2.8 | 2.3 | 1.6 | 3.0 |
| Cooling/heating cycle | 500 | 1000 | 1000 | 1000 | 1000 | 1000 | 500 | 500 | 1000 |
| reliability test | | | | | | | | | |

TABLE 6

| | Example | Example | Example | Example | Example | Example | Example | Example | Example |
|---|---|---|---|---|---|---|---|---|---|
| Item | 10 | 11 | 12 | 13 | 14 | 15 | 16 | 17 | 18 |
| Thermal conductivity | 1.2 | 1.2 | 1.2 | 1.2 | 1.5 | 1.6 | 0.8 | 1.0 | 1.1 |
| (W/mK) | | | | | | | | | |
| Elastic modulus at −50° C. | 1 | 68 | 110 | 20 | 35 | 30 | 10 | 20 | 75 |
| (MPa) | | | | | | | | | |
| Shear adhesive strength | 1.0 | 3.6 | 4.5 | 2.5 | 2.9 | 2.6 | 1.6 | 1.1 | 1.2 |
| at −50° C. (MPa) | | | | | | | | | |
| Shear strain at −50° C. | 2.5 | 2.2 | 1.6 | 3.0 | 2.4 | 2.4 | 1.8 | 1.5 | 1.3 |
| Cooling/heating cycle | 1000 | 1000 | 500 | 1000 | 1000 | 1000 | 500 | 500 | 500 |
| reliability test | | | | | | | | | |

TABLE 7

| | Example | Example | Example | Example | Comparative | Comparative | Comparative |
|---|---|---|---|---|---|---|---|
| Item | 19 | 20 | 21 | 22 | Example 1 | Example 2 | Example 3 |
| Thermal conductivity | 1.4 | 1.6 | 1.6 | 1.6 | 1.2 | 1.2 | 1.0 |
| (W/mK) | | | | | | | |
| Elastic modulus at −50° C. | 5 | 30 | 30 | 30 | 210 | 120 | 18000 |
| (MPa) | | | | | | | |
| Shear adhesive strength | 1.0 | 2.8 | 2.8 | 2.8 | 1.5 | 1 | 5.5 |
| at −50° C. (MPa) | | | | | | | |
| Shear strain at −50° C. | 1.2 | 2.8 | 3.0 | 3.3 | 0.4 | 0.6 | 0.2 |
| Cooling/heating cycle | 500 | 1000 | 1000 | 1000 | Peeled | Peeled | Cracked |
| reliability test | | | | | | | |

1. A resin composition comprising:
(A) a polyimide resin containing a siloxane unit;
(B) an epoxy resin;
(C) a siloxane diamine; and
(D) a thermally conductive filler.

2. The resin composition according to claim 1, wherein the thermally conductive filler (D) is spherical.

3. The resin composition according to claim 1, wherein the polyimide resin (A) containing a siloxane unit contains 20 mol % or more of a residue of acid anhydride represented by General Formula (1) with a total amount of tetracarboxylic acid anhydride residues being 100 mol % and contains 50 mol % or more of a residue of diamine represented by General Formula (2) with a total amount of diamine residues being 100 mol %: 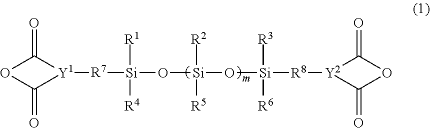
in General Formula (1), m represents an integer of 1 or more and 100 or less, R⁷ and R⁸ may be same or different and each represent an alkylene group having 1 to 30 carbon atoms or an arylene group, the arylene group may have a substituent, R¹ to R⁶ may be same or different and each represent an alkyl group having 1 to 30 carbon atoms, a phenyl group, or a phenoxy group, and Y¹ and Y² may be same or different and each represent a trivalent hydrocarbon group having 1 to 20 carbon atoms, and 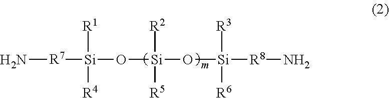
in General Formula (2), n represents an integer of 1 or more and 100 or less, R⁷ and R⁸ may be same or different and each represent an alkylene group having 1 to 30 carbon atoms or an arylene group, and R¹ to R⁶ may be same or different and each represent an alkyl group having 1 to 30 carbon atoms, a phenyl group, or a phenoxy group.

4. The resin composition according to claim 1, wherein the siloxane diamine (C) has a structure represented by General Formula (3) where N is 5 or more and 30 or less: 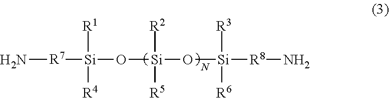
in General Formula (3), R⁷ and R⁸ may be same or different and each represent an alkylene group having 1 to 30 carbon atoms or an arylene group, and R¹ to R⁶ may be same or different and each represent an alkyl group having 1 to 30 carbon atoms, a phenyl group, or a phenoxy group.

5. The resin composition according to claim 1,
wherein the thermally conductive filler (D) exhibits at least 2 peaks as a result of peak division in a particle size distribution curve,
a thermally conductive filler constituting one of the peaks has an average particle diameter of 2 μm or more, and
a thermally conductive filler constituting another one of the peaks has an average particle diameter of 1 μm or less.

6. The resin composition according to claim 1, wherein a portion having an average particle diameter of 2 μm or more of the thermally conductive filler (D) has a specific surface area of 0.2 m²/g or more.

7. The resin composition according to claim 1, wherein a content of the siloxane diamine (C) is 5% by weight or more and 20% by weight or less with a total of the polyimide resin (A) containing a siloxane unit, the epoxy resin (B), and the siloxane diamine (C) being 100% by weight.

8. A sheet comprising a laminate and having a thickness of 50 μm or more and 400 μm or less, the laminate including a support and the resin composition according to claim 1 provided on the support.

9. A cured product obtained by curing the resin composition according to claim 1.

10. The cured product according to claim 9, wherein
an elastic modulus at −50° C. is 1 MPa or more and 100 MPa or less, and
a shear strain at −50° C. is 2 or more and 10 or less.

11. An electrostatic chuck comprising a laminate including a cooling plate, the cured product according to claim 9, and a ceramic plate in this order.

12. Plasma processing equipment comprising at least:
a plasma source; and
the electrostatic chuck according to claim 11.
